(19) United States
(12) Patent Application Publication
(10) Pub. No.: US 2026/0179711 A1
(43) Pub. Date: Jun. 25, 2026

(54) SEMICONDUCTOR MEMORY DEVICE INCLUDING ONE-TIME PROGRAMMABLE MEMORY DEVICE AND METHOD OF CONTROLLING THE SAME

(71) Applicant: SAMSUNG ELECTRONICS CO., LTD., Suwon-si (KR)

(72) Inventors: Soomin KIM, Suwon-si (KR); Joungyeal KIM, Suwon-si (KR); Hyunbo KIM, Suwon-si (KR); Minsoon CHOI, Suwon-si (KR)

(73) Assignee: SAMSUNG ELECTRONICS CO., LTD., Suwon-si (KR)

(21) Appl. No.: 19/271,280

(22) Filed: Jul. 16, 2025

(30) Foreign Application Priority Data
Dec. 24, 2024 (KR) 10-2024-0195612

(51) Int. Cl. G11C 29/44; G11C 29/00; G11C 29/14

(52) U.S. Cl. CPC G11C 29/44; G11C 29/14; G11C 29/76

(57) ABSTRACT

A semiconductor memory device includes a memory cell array including a plurality of memory cells storing data, a one-time programmable (OTP) memory device configured to provide updated OTP data, and a peripheral circuit configured to be initialized and control the memory cell array based on the updated OTP data. The OTP memory device includes an OTP cell array including a plurality of OTP cells, a driving circuit configured to output internal OTP data by reading out information stored in the OTP cell array, and an update selection circuit configured to receive external OTP data from an external device and selectively output the internal OTP data or the external OTP data to provide the updated OTP data.

### CROSS-REFERENCE TO RELATED APPLICATION

This U.S. non-provisional application claims priority under 35 USC § 119 to Korean Patent Application No. 10-2024-0195612, filed on Dec. 24, 2024, in the Korean Intellectual Property Office (KIPO), the disclosure of which is incorporated by reference herein in its entirety.

### BACKGROUND

### 1. Technical Field

Example embodiments relate generally to semiconductor integrated circuits, and more particularly to a semiconductor memory device including a one-time programmable memory device and a method of controlling a semiconductor memory device.

### 2. Discussion of the Related Art

A nonvolatile memory stores data that retains the data even when the power supply of the nonvolatile memory is interrupted. For example, the nonvolatile memory includes read only memory (ROM), magnetic discs, optical discs, and flash memory. Among nonvolatile memories, a one-time programmable (OTP) memory cannot change data once data is recorded in the OTP memory. When data is programmed into the OTP memory, the structure of the OTP cell, which is the storage unit for the data, is irreversibly changed such that a ‘0’ or ‘1’ may be stored. The OTP memory is used in a variety of applications as an embedded nonvolatile storage device to store information on repair, analog trimming, security codes, etc. for other semiconductor memory devices.

If an uncorrectable error occurs in the information stored in the OTPI memory, or if the information stored in the OTPI memory device becomes unsuitable due to a change in the state of the semiconductor device utilizing the information, the semiconductor memory device including the OTPI memory has to be discarded or performance of the semiconductor memory device may be degraded.

### SUMMARY

Some example embodiments may provide a one-time programmable (OTP) memory device, a semiconductor memory device including an OTP memory device and a method of controlling a semiconductor memory device, capable of efficiently updating information stored in the OTP memory device.

According to example embodiments, a semiconductor memory device includes a memory cell array including a plurality of memory cells storing data, a one-time programmable (OTP) memory device configured to provide updated OTP data, and a peripheral circuit configured to be initialized and control the memory cell array based on the updated OTP data. The OTP memory device includes an OTP cell array including a plurality of OTP cells, a driving circuit configured to output internal OTP data by reading out information stored in the OTP cell array, and an update selection circuit configured to receive external OTP data from an external device and selectively output the internal OTP data or the external OTP data to provide the updated OTP data.

According to example embodiments, a semiconductor memory device includes a memory cell array including a plurality of memory cells storing data, a one-time programmable (OTP) cell array including a plurality of OTP cells, a driving circuit configured to output internal OTP data by reading out information stored in the OTP cell array, an update selection circuit configured to receive external OTP data from an external device and selectively output the internal OTP data or the external OTP data to provide updated OTP data, and a peripheral circuit configured to be initialized and control the memory cell array based on the updated OTP data.

According to example embodiments, a method of controlling a semiconductor memory device including an one-time programmable (OTP) device, includes, outputting internal OTP data by reading out information stored in an OTP cell array, receiving external OTP data from a memory controller, providing updated OTP data by selectively outputting the internal OTP data or the external OTP data, and initializing the semiconductor memory device based on the updated OTP data.

The providing the updated OTP data includes: providing the internal OTP data as the updated OTP data in a preset mode; and provide the updated OTP data by replacing at least a portion of the internal OTP data with the external OTP data in a vector mode.

The method further includes selectively operating the semiconductor memory device in the preset mode or the vector mode based on a mode signal.

The method further includes: receiving a mode control value through a mode register write command transferred from the memory controller; storing the mode control value in one of mode registers configured to store control values to control operation of the semiconductor memory device; and generating the mode signal based on the mode control value stored in the one of the mode registers.

The OTP memory devices is configured to operate in the vector mode while the semiconductor memory device performs a hard reset operation by activating a reset signal during a power-on sequence.

The OTP memory device is configured to receive the external OTP data and operate in the vector mode while the semiconductor memory device performs a soft reset operation by activating a reset signal during a normal operation after a power-on sequence is completed.

The information stored in the OTP cell array includes row repair information to repair defective wordlines of the memory cell array, column repair information to repair defective bitlines of the memory cell array, test mode register set (TMRS) information to set test conditions of the semiconductor memory device, and trimming information to set voltage levels and signal timings of the semiconductor memory device.

The external OTP data is data to replace at least a portion of the TMRS information and the trimming information excluding the row repair information and the column repair information.

The method further includes: receiving encrypted external OTP data from the memory controller; and decrypting the encrypted external OTP data to restore the external OTP data.

The method further includes receiving the external OTP data through data pins of the semiconductor memory device from the memory controller.

The method further includes: receiving an update address indicating a range of information included in the external OTP data from the external device; generating an update selection signal based on the update address; and selecting the internal OTP data or the external OTP data, as the updated OTP data, based on the update selection signal.

The semiconductor memory device including the OTP memory device according to example embodiments may increase yield and lifespan of the semiconductor memory device by efficiently replacing the internal OTP data read from the OTP cell array with the external OTP data.

In addition, the semiconductor memory device including the OTP memory device according to example embodiments may increase degree of test freedom and improve test efficiency by testing the semiconductor memory device by replacing the internal OTP data with the external OTP data corresponding to various test conditions.

### BRIEF DESCRIPTION OF THE DRAWINGS

Example embodiments of the present disclosure will be more clearly understood from the following detailed description taken in conjunction with the accompanying drawings.

FIG. 1 is a block diagram illustrating a one-time programmable (OTP) memory device according to example embodiments.

FIG. 2 is a flowchart illustrating a method of controlling a semiconductor memory device including an OTP memory device according to example embodiments.

FIG. 3 is a block diagram illustrating a memory system according to example embodiments.

FIG. 4 is a block diagram illustrating a test system according to example embodiments.

FIG. 5 is a block diagram illustrating a semiconductor memory device including an OTP memory device according to example embodiments.

FIG. 6 is a diagram illustrating a bank array included in the semiconductor memory device of FIG. 5.

FIG. 7 is a block diagram illustrating an OTP memory device according to example embodiments.

FIG. 8 is a block diagram illustrating an example embodiment of an OTP cell array included in an OTP memory device according to example embodiments.

FIG. 9 is a diagram illustrating an example embodiment of an OTP fuse set included in the OTP cell array of FIG. 8.

FIG. 10 is a timing diagram illustrating an example embodiment of a sensing operation of an OTP memory device according to example embodiments.

FIG. 11 is a block diagram illustrating an example embodiment of an update selection circuit included in an OTP memory device according to example embodiments.

FIGS. 12 and 13 are timing diagrams illustrating example embodiments of operations in a preset mode and a vector mode of an OTP memory device according to example embodiments.

FIG. 14 is a diagram illustrating an example embodiment of a latch circuit included in an OTP memory device according to example embodiments.

FIG. 15 is a circuit diagram illustrating an example embodiment of a 1-bit latch included in the latch circuit of FIG. 14.

FIG. 16 is a timing diagram illustrating an example embodiment of an operation of an OTP memory device according to example embodiments.

FIG. 17 is a diagram illustrating example embodiments of information stored in an OTP memory device according to example embodiments.

FIG. 18 is a diagram illustrating an example embodiment of an operation of an update selection circuit included in an OTP memory device according to example embodiments.

FIG. 19 is a block diagram illustrating a semiconductor memory device including an OTP memory according to example embodiments.

FIG. 20 is a circuit diagram illustrating an example embodiment of an OTP cell included in an OTP memory device according to example embodiments.

FIG. 21 is a cross-sectional diagram illustrating an example embodiment of a structure of the OTP cell of FIG. 20.

FIG. 22 is a circuit diagram illustrating an example embodiment of an OTP cell included in an OTP memory device according to example embodiments.

FIGS. 23 and 24 are circuit diagrams illustrating example embodiments of an OTP cell array included in an OTP memory device according to example embodiments.

FIG. 25 is a block diagram illustrating a semiconductor memory device according to example embodiments.

FIG. 26 is a block diagram illustrating a mobile system including an OTP memory device according to example embodiments.

FIG. 27 is a structural diagram illustrating a semiconductor package including a stacked memory device according to example embodiments.

### DETAILED DESCRIPTION OF THE EXAMPLE EMBODIMENTS

Various example embodiments will be described more fully hereinafter with reference to the accompanying drawings, in which some example embodiments are shown. In the drawings, like numerals refer to like elements throughout. The repeated descriptions may be omitted.

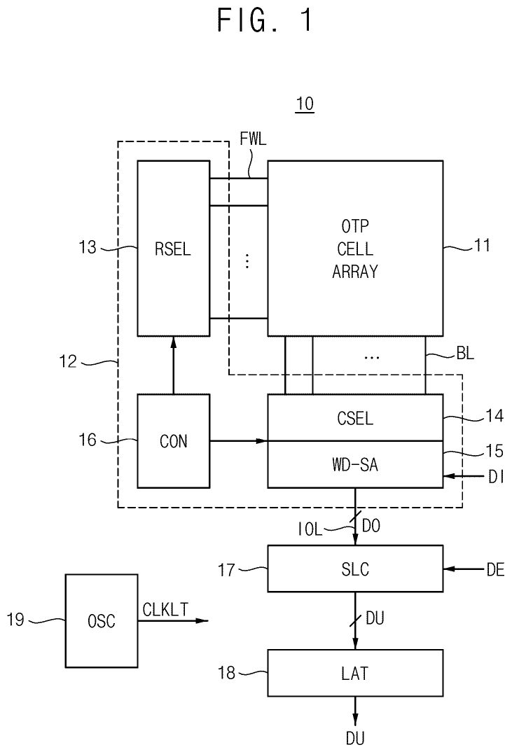

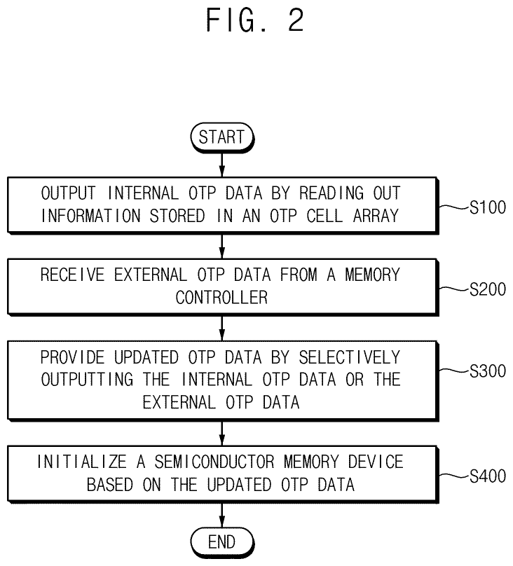

FIG. 1 is a block diagram illustrating a one-time programmable (OTP) memory device according to example embodiments, and FIG. 2 is a flowchart illustrating a method of controlling a semiconductor memory device including an OTP memory device according to example embodiments.

Referring to FIG. 1, an OTP memory device 10 may include a memory cell array 11, a driving circuit 12, an update selection circuit (SLC) 17, and a latch circuit (LAT) 18. The driving circuit 12 may include a row selection circuit (RSEL) 13, a column selection circuit (CSEL) 14, a write-read circuit (WD-SA) 15, and a control circuit (CON) 16. According to example embodiments, the update selection circuit 17 and the latch circuit 18 may be considered to be disposed outside the OTP memory device 10 and included in a device or system including the OTP memory device 10.

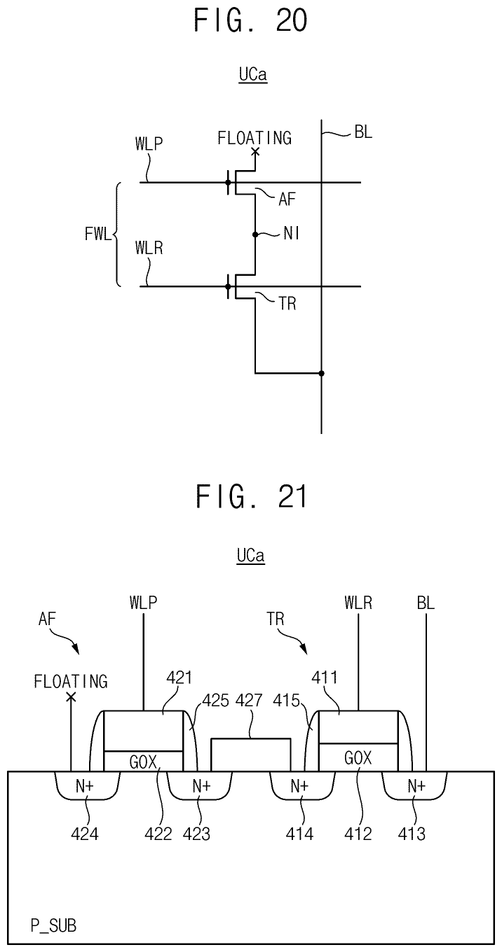

The memory cell array 11 includes a plurality of OTP cells, which are respectively connected to a plurality of bitlines BL and a plurality of wordlines FWL. As will be described below with reference to FIG. 20, each wordline FWL may include a voltage wordline WLP and a read wordline WLR.

The row selection circuit 13 may include a row decoder for selecting a wordline FWL corresponding to a row address and a voltage driver for providing voltages to be applied to the wordlines FWL. The column selection circuit 14 may include a column gate circuit and a column decoder for selecting a bitline BL corresponding to a column address. The column decoder may generate column selection signals based on the column address and a column selection enable signal. The column gate circuit may include a plurality of switches that are selectively turned on in response to the column selection signals. One switch corresponding to the column address among the switches may be turned on to select a bitline.

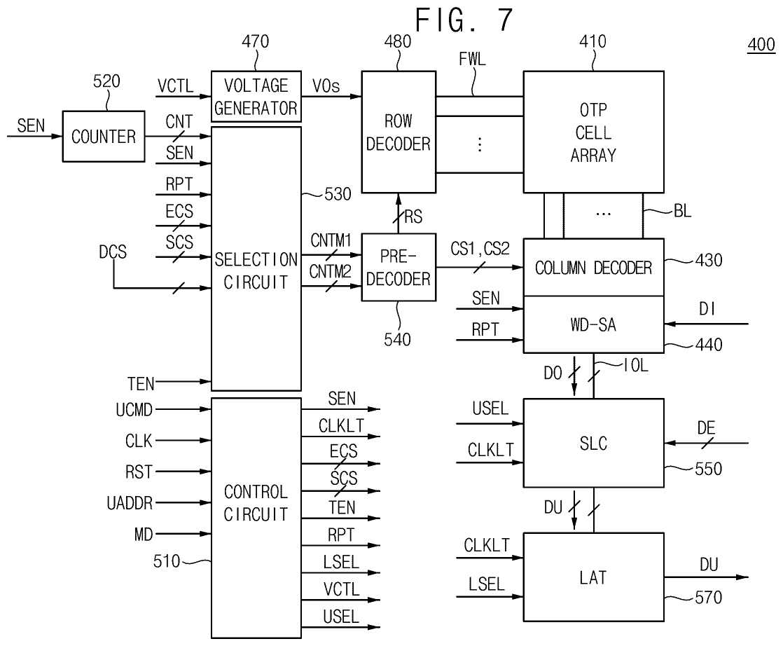

The write-read circuit 15 may include a read sense amplifier SA and a write driver WD. The write-read circuit 15 is connected to the bitlines through the column selection circuit 14. The read sense amplifier SA senses data stored in the OTP cell and performs a read operation to provide internal OTP data DO. The write driver WD performs a write operation to store program data DI in the OTP cell. The write driver WD may be formed integrally with the read sense amplifier SA or may be formed as a separate circuit distinct from the read sense amplifier SA. The control circuit 16 may provide control signals, row address signals, column address signals, etc. for controlling the overall operation of the OTP memory device 10. In an example embodiment, the control circuit 16 may be implemented as control logic circuit dedicated to the OTP memory device 10. In another example embodiment, at least a portion of the control circuit 16 may be included in another logic circuit within a semiconductor integrated circuit including the OTP memory device 10. A more detailed configuration of the OTP memory device 10 will be described below with reference to the example embodiment of FIG. 7.

Referring to FIGS. 1 and 2, the driving circuit 12 of the OTP memory device 10 may read out information stored in the OTP cell array 11 and output internal OTP data DO (S100). The read operation of the internal OTP data DO will be described below with reference to FIG. 10.

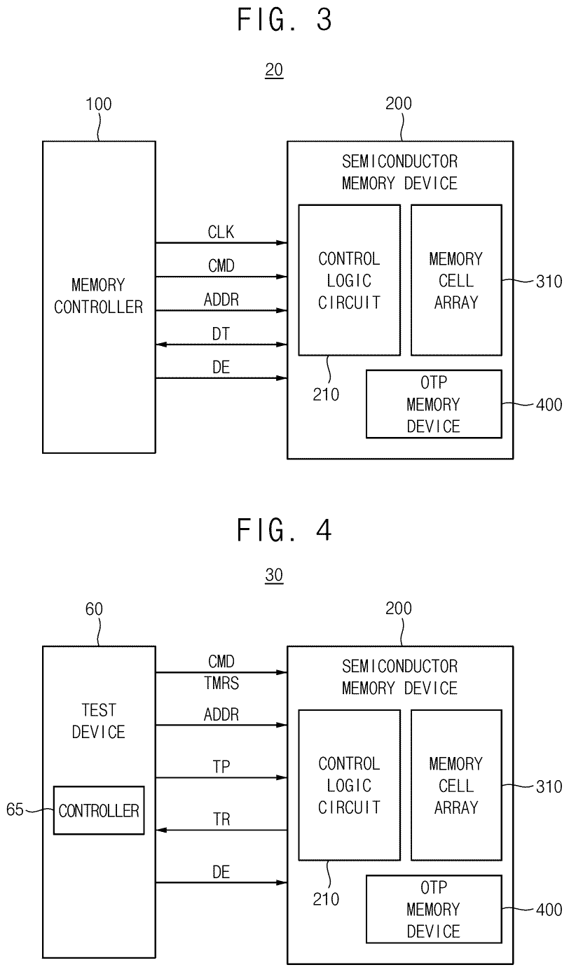

The update selection circuit 17 may receive external OTP data DE from an external device (S200). In an example embodiment, the external device may be a memory controller 100 of FIG. 3. In another example embodiment, the external device may be a test device 60 of FIG. 4.

The update selection circuit 17 may provide updated OTP data DU by selectively outputting the internal OTP data DO or the external OTP data DE (S300). The operation of the update selection circuit 17 will be described below with reference to FIG. 10.

The semiconductor memory device including the OTP memory device 10 may be initialized based on the updated OTP data DU (S400). As will be described below, during a hard reset operation, the semiconductor memory device may be initialized based on the updated OTP data DU corresponding to the internal OTP data DO. On the other hand, during a soft reset operation, the semiconductor memory device may be initialized based on the updated OTP data DU in which at least a portion of the internal OTP data DO is replaced with the external OTP data DE.

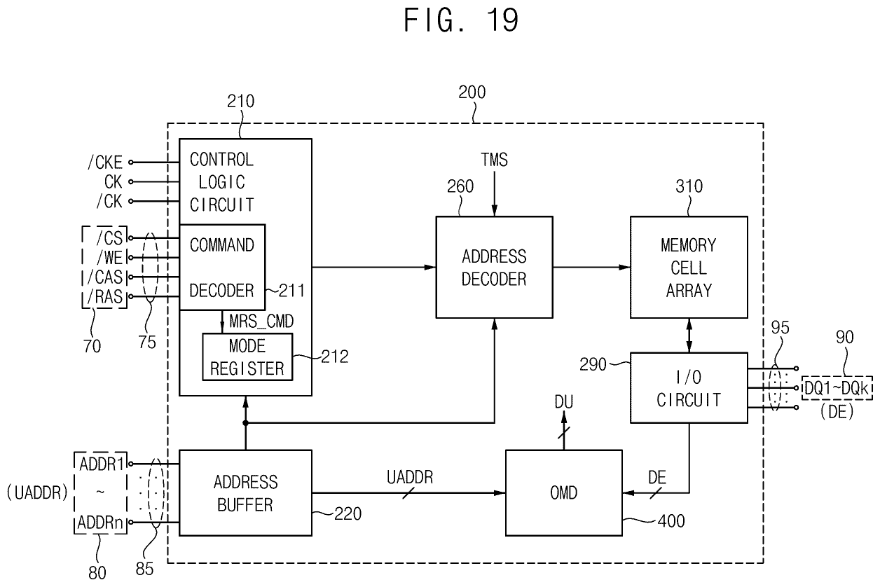

Referring again to FIG. 1, the latch circuit 18 may latch and store the updated OTP data DU provided from the update selection circuit 17. As will be described with reference to FIGS. 17 and 18, the latch circuit 18 may store the updated OTP data DU by grouping the updated OTP data DU by type of information, and the updated OTP data DU stored in the latch circuit 18 may be provided to associated components, information by information.

According to example embodiments, the OTP memory device 10 may further include an oscillator (OSC) 19 that generates a latch clock signal CLKLT. In this case, the OTP memory device 10 may operate based on the latch clock signal CLKLT even without a supply of a clock signal from the outside. For example, the OTP memory device 10 may perform a sensing operation or a read operation to read out the internal OTP data DO from the OTP cell array 11 based on the latch clock signal CLKLT even before the power-on sequence of the semiconductor memory device including the OTP memory device 10 is completely completed.

FIG. 3 is a block diagram illustrating a memory system according to example embodiments.

Referring to FIG. 3, a memory system 20 may include a memory controller 100 and a semiconductor memory device 200.

The memory controller 100 controls the overall operation of the memory system 20 and controls the overall data exchange between an external host and the semiconductor memory device 200. For example, the memory controller 100 may control the semiconductor memory device 200 to write data or read data according to a request from the host.

In addition, the memory controller 100 may control the operation of the semiconductor memory device 200 by applying operation commands for controlling the semiconductor memory device 200.

According to example embodiments, the semiconductor memory device 200 may include a dynamic random access memory (DRAM), a double data rate 4(DDR4 ) synchronous DRAM (SDRAM), a low power DDR4 (LPDDR4) SDRAM, or an LPDDR5 SDRAM having dynamic memory cells.

The memory controller 100 may transmit a clock signal CLK, a command CMD, and an address ADDR to the semiconductor memory device 200, and may exchange data DT with the semiconductor memory device 200.

The semiconductor memory device 200 may include a memory cell array 310 in which data DT is stored, a control logic circuit 210, and an OTP memory device 400.

The memory controller 100 may provide external OTP data DE to the semiconductor memory device 200. The memory controller 100 may receive the external OTP data DE stored in a nonvolatile memory that is disposed inside or outside the memory controller 100, and transmit the external OTP data DE to the semiconductor memory device 200. The OTP memory device 400 may provide the updated OTP data DU by replacing at least a portion of the internal OTP data DO read from the OTP cell array with the external OTP data DE provided from the memory controller 100.

The internal OTP data DO may include errors due to an operation error of the OTP memory device 400, deterioration of the OTP cells, etc. If an error exists in the internal OTP data DO, the performance of the semiconductor memory device 200 deteriorates, and if the error is serious, the semiconductor memory device 200 has to be discarded. In addition, in order to improve the performance of the OTP memory device 400, it is necessary to update information stored in the OTP memory device 400.

The OTP memory device 400 and the semiconductor memory device 200 including the OTP memory device 400 according to example embodiments may increase yield and lifespan of the semiconductor memory device by efficiently replacing the internal OTP data DO read from an OTP cell array with the external OTP data DE.

FIG. 4 is a block diagram illustrating a test system according to example embodiments.

Referring to FIG. 4, a test system 30 may include a semiconductor memory device 200 as a device under test (DUT) and a test device 60 that performs a test on the semiconductor memory device 200. Although FIG. 4 illustrates one semiconductor memory device 200, the test device 60 may be connected simultaneously to a plurality of semiconductor memory devices to perform parallel tests.

The semiconductor memory device 200 may include a memory cell array 310, a control logic circuit 210, and an OTP memory device 400.

The test device 60 may perform a test operation on the memory cell array 310 of the semiconductor memory device 200. To this end, the test device 60 may provide a command CMD, a test mode register set (TMRS) command, an address ADDR, and test pattern data TP to the semiconductor memory device 200, and receive test result data TR from the semiconductor memory device 200. Based on the test result data TR, measures may be taken to improve design of the semiconductor memory device 200, correct an error of the semiconductor memory device 200, or improve performance of the semiconductor memory device 200.

The test device 60 may include a controller 65 that controls a test sequence for the semiconductor memory device 200. The controller 65 may generate external OTP data DE corresponding to a test condition and provide the external OTP data DE to the semiconductor memory device 200. The OTP memory device 400 may provide updated OTP data DU by replacing at least a portion of the internal OTP data DO read out from the OTP cell array with the external OTP data DE provided from the test device 60. The semiconductor memory device 200 is initialized based on the external OTP data DE corresponding to the test condition, and the test device 60 may perform a test corresponding to the test condition. The test device 60 may repeatedly provide different external OTP data DE corresponding to various test conditions to the semiconductor memory device 200, and thus tests corresponding to various conditions may be performed. The OTP memory device 400 and the semiconductor memory device 200 including the OTP memory device 400 according to example embodiments may increase degree of test freedom and improve test efficiency by testing the semiconductor memory device 200 by replacing the internal OTP data DO with the external OTP data corresponding to various test conditions.

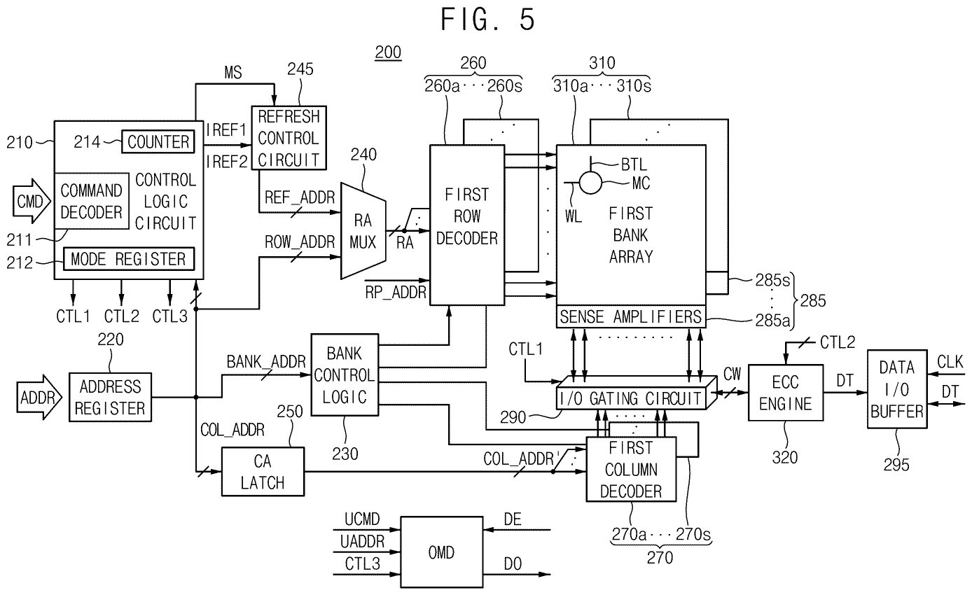

FIG. 5 is a block diagram illustrating a semiconductor memory device including an OTP memory device according to example embodiments.

Referring to FIG. 5, a semiconductor memory device 200 may include a control logic circuit 210, an address register 220, a bank control logic 230, a refresh control circuit 245, a row address multiplexer 240, a column address latch 250, a row decoder 260, a column decoder 270, a memory cell array 310, a sense amplifier circuit 285, an input/output gating circuit 290, an ECC engine 320, a data input/output buffer 295, and an OTP memory device 400. The memory cell array 310 and the sense amplifier circuit 285 may be referred to as a memory core. The remaining components may be referred to as peripheral circuits.

The memory cell array 310 may include a plurality of bank arrays 310a to 310s. In addition, the row decoder 260 may include a plurality of row decoders 260a to 260s connected to a plurality of bank arrays 310a to 310s, the column decoder 270 may include a plurality of column decoders 270a to 270s connected to a plurality of bank arrays 310a to 310s, and the sense amplifier circuit 285 may include a plurality of sense amplifiers 285a to 285s connected to a plurality of bank arrays 310a to 310s. The plurality of bank arrays 310a to 310s, the plurality of row decoders 260a to 260s, the plurality of column decoders 270a to 270s, and the plurality of sense amplifiers 285a to 285s may form first to sixteenth banks. Each of the plurality of bank arrays 310a to 310s may include a plurality of wordlines WL, a plurality of bitlines BTL, and a plurality of memory cells MC formed at points where the wordlines WL and the bitlines BTL intersect. The address register 220 may receive an address ADDR including a bank address BANK_ADDR, a row address ROW_ADDR, and a column address COL_ADDR from the memory controller (e.g., 100 in FIG. 3). The address register 220 may provide the received bank address BANK_ADDR to the bank control logic 230, provide the received row address ROW_ADDR to the row address multiplexer 240 and the address comparator 350, and provide the received column address COL_ADDR to the column address latch 250.

The bank control logic 230 may generate bank control signals in response to the bank address BANK_ADDR. In response to the bank control signals, a row decoder corresponding to the bank address BANK_ADDR among the plurality of row decoders 260a to 260s may be activated, and a column decoder corresponding to the bank address BANK_ADDR among the plurality of column decoders 270a to 270s may be activated.

The row address multiplexer 240 may receive the row address ROW_ADDR from the address register 220 and a refresh row address REF_ADDR from the refresh control circuit 245. The row address multiplexer 240 may selectively output the row address ROW_ADDR or the refresh row address REF_ADDR as the row address RA. The row address RA output from the row address multiplexer 240 may be applied to each of the plurality of row decoders 260a to 260s.

The refresh control circuit 245 may output the refresh row address REF_ADDR that sequentially increases or decreases in response to a first refresh control signal IREF1 or a second refresh control signal IREF2 provided from the control logic circuit 210.

The control logic circuit 210 may apply the first refresh control signal IREF1 to the refresh control circuit 245 whenever the auto refresh command is applied when the command CMD from the memory controller 100 is an auto refresh command.

The control logic circuit 210 may apply the second refresh control signal IREF2 that is activated until a self-refresh exit command is applied after receiving the self-refresh entry command, to the refresh control circuit 245, when the command CMD from the memory controller 100 is a self-refresh entry command. The refresh control circuit 245 may sequentially increase or decrease the refresh row address REF_ADDR whenever the first refresh control signal IREF1 is applied or while the second refresh control signal IREF2 is activated.

Among the plurality of row decoders 260a to 260s, a row decoder activated by the bank control logic 230 may decode a row address RA or a repair address RP_ADDR output from the row address multiplexer 240 to activate a wordline corresponding to the row address RA or a redundancy wordline corresponding to the repair address RP_ADDR. For example, the activated row decoder may apply a wordline driving voltage to a wordline corresponding to the row address RA or a redundancy wordline corresponding to the repair address RP_ADDR.

The column address latch 250 may receive the column address COL_ADDR from the address register 220 and temporarily store the received column address COL_ADDR. In addition, the column address latch 250 may incrementally increase the received column address COL_ADDR in the burst mode. The column address latch 250 may apply the temporarily stored column address COL_ADDR or the incrementally increased column address COL_ADDR′ to each of the plurality of column decoders 270a to 270s.

A column decoder activated by the bank control logic 230 among the plurality of column decoders 270a to 270s may activate a sense amplifier corresponding to the bank address BANK_ADDR and the column address COL_ADDR or COL_ADDR′ through the corresponding input/output gating circuit 290. The input/output gating circuit 290 may include circuits for gating input/output data, input data mask logic, read data latches for storing data output from a plurality of bank arrays 310a to 310s, and write drivers for writing data to a plurality of bank arrays 310a to 310s.

A codeword CW to be read from one of the plurality of bank arrays 310a to 310s may be detected by a sense amplifier corresponding to the one bank array and stored in the read data latches. The codeword CW stored in the read data latches may be provided to the memory controller 100 through the data input/output buffer 295 after ECC decoding is performed by the ECC engine 320. Data DT to be written to one of the bank arrays 310a to 310s is provided to the ECC engine 320, the ECC engine 320 generates parity bits based on the data DT, and provides the data DT and the parity bits as a codeword CW to the input/output gating circuit 290, and the input/output gating circuit 290 may write the codeword CW to a subpage of a target page of the one bank array through the write drivers.

The data input/output buffer 295 may provide data DT to the ECC engine 320 based on a clock signal CLK provided from the memory controller 100 in a write operation, and may provide data DT provided from the ECC engine 320 to the memory controller 100 in a read operation.

The OTP memory device 400 may receive external OTP data DE from an external device, such as the memory controller 100 of FIG. 3 and the test device 60 of FIG. 4. The OTP memory device 400 may replace at least a portion of internal OTP data DO read from an OTP cell array with the external OTP data DE provided from the external device to provide updated OTP data DU. As will be described below with reference to FIG. 7, the OTP memory device 400 may receive the external OTP data DE and output the updated OTP data DU based on an update command UCMD and an update address UADDR provided from the external device. The external OTP data DE may be provided from the external device to the semiconductor memory device 200 along with the update command UCMD. The update address UADDR may indicate a range of information included in the external OTP data DE.

The control logic circuit 210 may control the operation of the semiconductor memory device 200. For example, the control logic circuit 210 may generate control signals such that the semiconductor memory device 200 performs a write operation or a read operation. The control logic circuit 210 may include a command decoder 211 that decodes a command CMD received from the memory controller 100 and mode registers 212 for setting an operation mode of the semiconductor memory device 200.

For example, the command decoder 211 may decode a write enable signal, a row address strobe signal, a column address strobe signal, a chip selection signal, etc. to generate the control signals corresponding to the command CMD.

In particular, the control logic circuit 210 may generate, by decoding the command CMD, a first control signal CTL1 for controlling the input/output gating circuit 290, a second control signal CTL2 for controlling the ECC engine 320, and a third control signal CTL3 for controlling the OTP memory device 400.

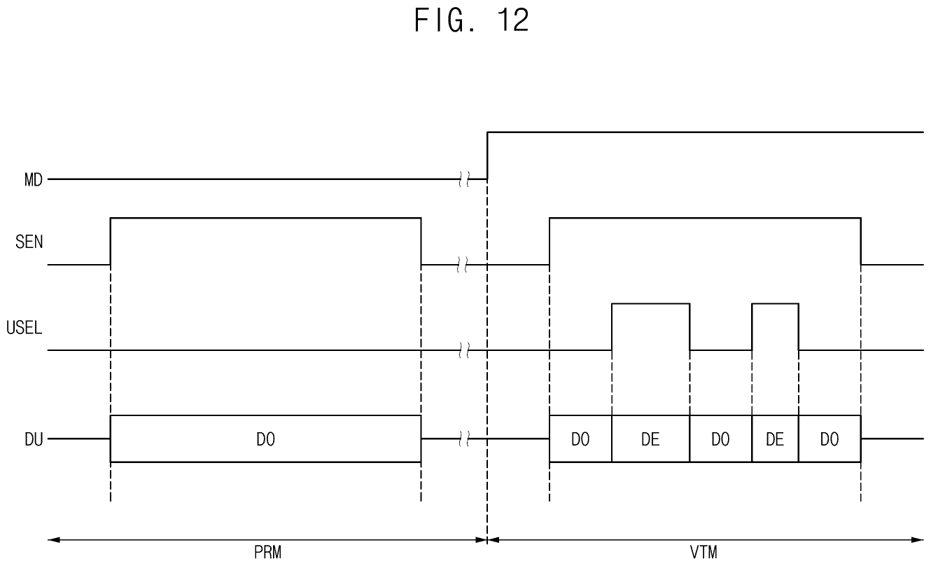

The mode registers 212 may store control values for controlling the operation of the semiconductor memory device 200. The third control signal CTL3 may include a mode signal MD as will be described below with reference to FIGS. 7 and 12. The mode signal MD may be generated based on a mode control value stored in one of the mode registers 212. The mode control value may be set through a mode register write command MRW provided from the external device.

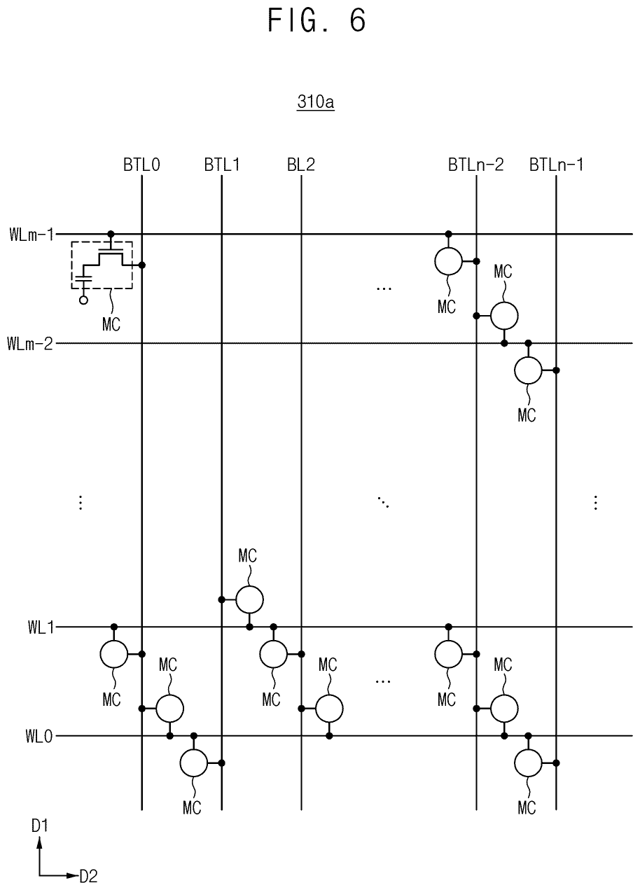

FIG. 6 is a diagram illustrating a bank array included in the semiconductor memory device of FIG. 5.

Referring to FIG. 6, the first bank array 310a includes a plurality of wordlines WL0 to WLm-1 (m is an even integer greater than or equal to 2), a plurality of bitlines BTL0 to BTLn-1 (n is an even integer greater than or equal to 2), and a plurality of memory cells MC arranged at intersections between the wordlines WL0 to WLm-1 and the bitlines BTL0 to BTLn-1. Each memory cell MC may have a DRAM cell structure. The DRAM cell may include a cell capacitor and a cell transistor. The bitlines BTL0 to BTLn-1 may extend in a first direction D1, and the wordlines WL0 to WLm-1 may extend in a second direction D2.

FIG. 7 is a block diagram illustrating an OTP memory device according to example embodiments.

Referring to FIG. 7, an OTP memory device 400 may include an OTP cell array 410, a column decoder 430, a write-detect circuit (WD_SA) 440, a voltage generator 470, a row decoder 480, a control circuit 510, a counter 520, a selection circuit 530, a pre-decoder 540, an update selection circuit (SLC) 550, and a latch circuit (LAT) 570.

The OTP cell array 410 includes a plurality of OTP cells, which are connected to a plurality of bitlines BL and a plurality of wordlines FWL. As will be described below with reference to FIG. 20, each wordline FWL may include a voltage wordline WLP and a read wordline WLR.

The control circuit 510 may receive external OTP data DE from an external device of the OTP memory device 400 in response to an update command UCMD and an update address UADDR provided from the outside. In addition, the control circuit 510 may control the operation of the OTP memory device 400 based on a clock signal CLK, a reset signal RST, and a mode signal MD provided from the outside.

The control circuit 510 generates a detection signal SEN, a latch clock signal CLKLT, an external column selection signal ECS, a detection column selection signal SCS, a test signal TEN, a rupture signal RPT, a latch selection signal LSEL, a voltage control signal VCTL, and an update selection signal USEL to control the write-detect circuit 440, the voltage generator 470, the counter 520, the selection circuit 530, the update selection circuit 550, and the latch circuit 570 based on the update command UCMD, the update address UADDR, the clock signal CLK, the reset signal RST, and the mode signal MD, and provides the detection signal SEN, the latch clock signal CLKLT, the external column selection signal ECS, the detection column selection signal SCS, the test signal TEN, the rupture signal RPT, the latch selection signal LSEL, the voltage control signal VCTL, and the update selection signal USEL to the associated components.

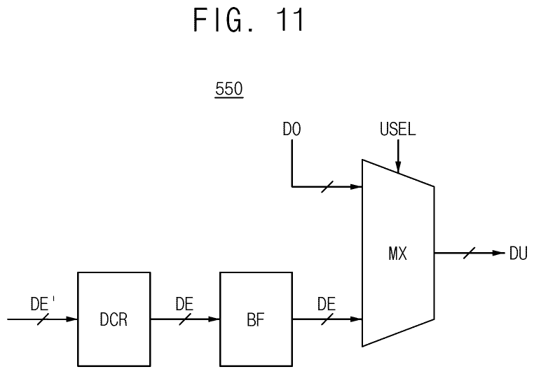

The control circuit 510 of the OTP memory device 400 may receive an update address UADDR indicating a range of information included in the external OTP data DE from an external device, for example, the memory controller 100 of FIG. 3. The control circuit 510 may generate an update selection signal USEL based on the update address UADDR, as will be described with reference to FIGS. 11 and 12. The update selection circuit 550 may selectively output the internal OTP data DO or the external OTP data DE based on the update selection signal USEL to provide the updated OTP data DU.

The column decoder 430 may be connected to the OTP cell array 410 through bitlines BL. The column decoder 430 may select some of the bitlines BL in response to the first column selection signal CS1 and the second column selection signal CS2 provided from the pre-decoder 540.

The write-detect circuit 440 is connected to the column decoder 430, and writes input data DI to the OTP cell array 410 through the column decoder 430 in response to the detection signal SEN and the rupture signal RPT, and reads out the internal OTP data DO from the OTP cell array 410 and provides the internal OTP data DO through the input/output lines IOL.

The write-detect circuit 440 may include a write driver and a sense amplifier. The sense amplifier performs a read operation that senses data stored in an OTP cell and provides read data. The write driver performs a write operation that stores the write data in the OTP cell. The write driver may be formed integrally with the sense amplifier, or may be formed as a separate circuit distinct from the sense amplifier.

The row decoder 480 may be connected to the OTP cell array 410 via wordlines FWL. The row decoder 480 may determine one of the plurality of wordlines FWL as a selected wordline based on a row selection signal RS provided from the pre-decoder 540, and may determine the remaining wordlines excluding the selected wordline among the plurality of wordlines FWL as unselected wordlines.

The voltage generator 470 may generate operating voltages VO based on a voltage control signal VCTL provided from the control circuit 510, and may apply the operating voltages VO to the wordlines FWL via the row decoder 480.

The counter 520 may generate a count signal CNT that sequentially increases in response to the activation of the detection signal SEN and provide the count signal CNT to the selection circuit 530. The selection circuit 530 receives the detection signal SEN, the rupture signal RPT, the external column selection signal ECS, the detection column selection signal SCS, and the test signal TEN from the control circuit 510, receives the count signal CNT from the counter 520, and generates a first selection count signal CNTM1 related to a row address of each of a plurality of OTP fuse sets included in the OTP cell array 410 and a second selection count signal CNTM2 related to a column address of each of the OTP fuse sets based on the count signal CNT, the detection signal SEN, and the rupture signal RPT, and provides the first selection count signal CNTM1 and the second selection count signal CNTM2 to the pre-decoder 540.

The pre-decoder 540 may generate the row selection signal RS for selecting one of a plurality of OTP cell rows of an OTP cell array 410 based on the first selection count signal CNTM1 and the second selection count signal CNTM2, the first column selection signal CS1 for selecting one of the OTP fuse sets of the selected OTP cell row, and the second column selection signal CS2 for selecting one OTP cell from the selected OTP fuse set, and may provide the row selection signal RS to the row decoder 480 and provide the first column selection signal CS1 and the second column selection signal CS2 to the column decoder 430.

The column decoder 430 may select one OTP fuse set among the plurality of OTP fuse sets of one OTP cell row based on the first column selection signal CS1, and may select one OTP cell from the selected OTP fuse set based on the second column selection signal CS2.

The write-detect circuit 440 may program input data DI to a target OTP fuse set among the plurality of OTP fuse sets of the OTP cell array 410 through the column decoder 430 in response to the activation of the rupture signal RPT.

The write-detect circuit 440 may read out the internal OTP data DO stored in the plurality of OTP fuse sets of the OTP cell array 410 in a read operation in response to the activation of the detection signal SEN, and provide the internal OTP data DO to the update selection circuit 550. The update selection circuit 550 may receive the internal OTP data DO output from the write-detect circuit 440 and the external OTP data DE provided from an external device. The update selection circuit 550 may provide the updated OTP data DU by replacing at least a portion of the internal OTP data DO with the external OTP data DE based on the latch clock signal CLKLT and the update selection signal USEL. The latch circuit 570 may latch and store the updated OTP data DU output from the update selection circuit 550 based on the latch clock signal CLKLT and the latch selection signal LSEL.

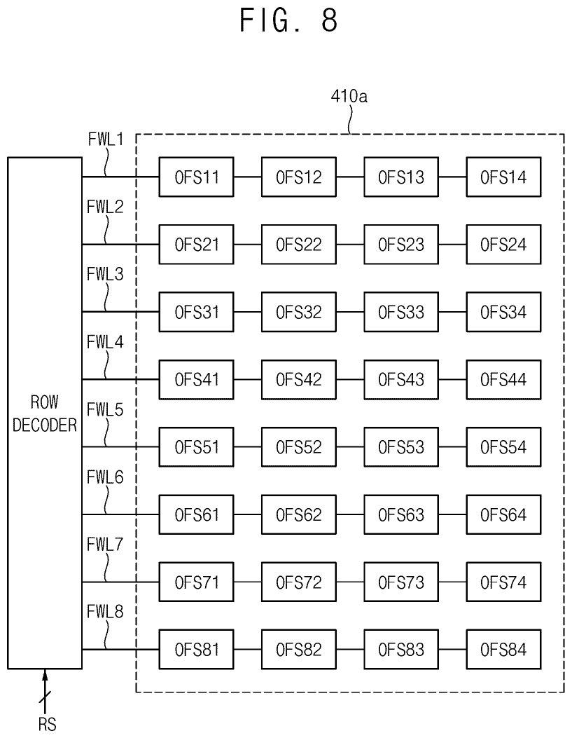

FIG. 8 is a block diagram illustrating an example embodiment of an OTP cell array included in an OTP memory device according to example embodiments.

In FIG. 8, a row decoder 480 is also illustrated for convenience of description. In addition, FIG. 8 illustrates an example in which an OTP cell array 410a includes eight OTP cell rows, and each of the OTP cell rows includes four OTP fuse sets, for convenience of illustration and description. However, the number of OTP cell rows and the number of OTP fuse sets may be variously changed.

Referring to FIG. 8, four OTP fuse sets OFS11, OFS12, OFS13, and OFS14 are connected to a wordline FWL1, four OTP fuse sets OFS21, OFS22, OFS23, and OFS24 are connected to a wordline FWL2, four OTP fuse sets OFS31, OFS32, OFS33, and OFS34 are connected to a wordline FWL3, four OTP fuse sets OFS41, OFS42, OFS43, and OFS44 are connected to a wordline FWL4, four OTP fuse sets OFS51, OFS52, OFS53, and OFS54 are connected to a wordline FWL5, four OTP fuse sets OFS61, OFS62, OFS63, and OFS64 are connected to a wordline FWL6, four OTP fuse sets OFS62, OFS63, and OFS64 are connected to a wordline FWL7, and four OTP fuse sets OFS81, OFS82, OFS83, and OFS84 are connected to a wordline FWL8.

The row decoder 480 selects an OTP cell row connected to one of the wordlines FWL1 to FWL8 based on a row selection signal RS, and one of the four OTP fuse sets of the selected OTP cell row may be selected by a first column selection signal CS1. Assuming that an OTP cell row connected to the wordline FWL1 is selected by the row selection signal RS, the OTP fuse set OFS11 may be selected by a first bit CS1[0] of the first column selection signal CS1, the OTP fuse set OFS12 may be selected by a second bit CS1[1] of the first column selection signal CS1, the OTP fuse set OFS13 may be selected by a third bit CS1[2] of the first column selection signal CS1, and the OTP fuse set OFS14 may be selected by a fourth bit CS1[3] of the first column selection signal CS1. Each of the OTP fuse sets may store unit information, and the OTP fuse sets may be grouped to store information by group as will be described with reference to FIGS. 17 and 18.

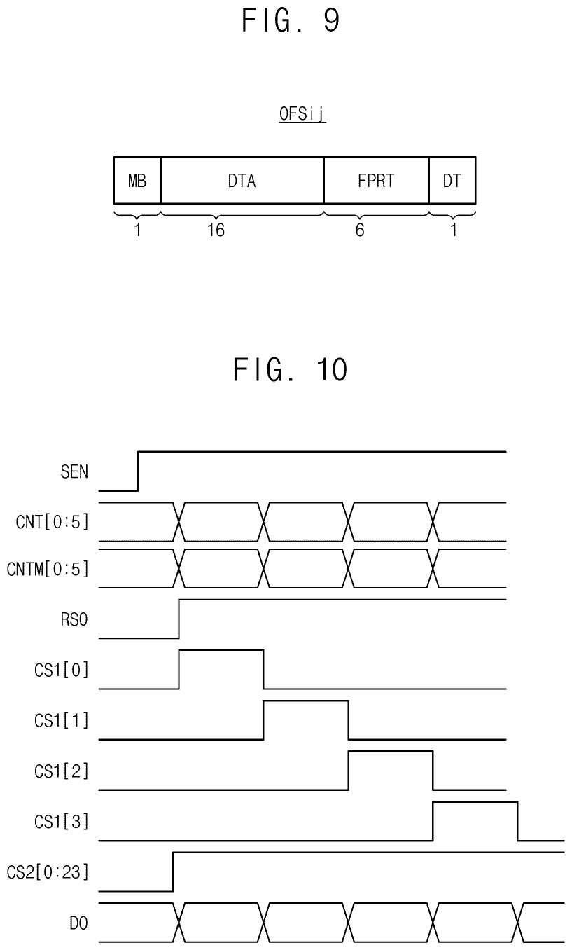

FIG. 9 is a diagram illustrating an example embodiment of an OTP fuse set included in the OTP cell array of FIG. 8.

Referring to FIG. 9, an OTP fuse set OFSij, where i is one of 1 to 8, and j is one of 1 to 4, may store a master bit MB, fuse data DTA, parity data FPRT, and a dirty bit DT.

The master bit MB is composed of 1 bit and may indicate whether the fuse data DTA and the parity data FPRT are programmed in the OTP fuse set OFSij. The fuse data DTA is composed of 16 bits and may include a defective address, and the parity data FPRT is composed of 6 bits and may be used to correct a single bit error of the fuse data DTA. The dirty bit DT is composed of 1 bit and may indicate whether an uncorrectable error is detected in the fuse data DTA. If an uncorrectable error is detected in the fuse data DTA, the dirty bit DT may be programmed to invalidate the OTP fuse set OFSij.

Generally, when data is composed of 2t bits and parity data is composed of (t+1) bits, a 1-bit error included in the data may be corrected, and when the parity data is composed of (t+2) bits, a 1-bit error included in the data may be corrected and a 2-bit error may be detected. The bit numbers of the fuse data DTA and the parity data FPRT illustrated in FIG. 9 are exemplary, and these bit numbers may be determined in various ways.

FIG. 10 is a timing diagram illustrating an example embodiment of a sensing operation of an OTP memory device according to example embodiments.

Referring to FIGS. 7 and 10, in a sensing operation or a read operation, a detection signal SEN is activated to a high level, and a rupture signal RPT and a test signal TEN are deactivated to a low level.

The counter 520 provides a count signal CNT[0:5] that sequentially increases while the detection signal SEN is activated to the selection circuit 530, and the selection circuit 530 provides a count selection signal CNTM[0:5] to the pre-decoder 540 based on the count signal CNT[0:5] in response to the activated detection signal SEN.

The pre-decoder 540 activates a row selection signal RS0 for selecting a wordline FWL1 based on the count selection signal CNTM[0:5], sequentially activates bits CS1[0], CS1[1], CS1[2], and CS1[3] of a first column selection signal CS1 for selecting OTP fuse sets OFS11, OFS12, OFS13, and OFS14 connected to the wordline FWL1, and activates a second column selection signal CS2[0:23] for selecting OTP cells included in each of the OTP fuse sets OFS11, OFS12, OFS13, and OFS14 while the row selection signal RS0 is activated.

Accordingly, the fuse data DTA and parity data FPRT stored in each of the OTP fuse sets OFS11, OFS12, OFS13, and OFS14 are read out as the internal OTP data DO through the column decoder 430 and the write-detect circuit 440. The fuse data DTA and the parity data FPRT are provided to an ECC engine (not shown), and the ECC engine may perform ECC decoding based on the parity data FPRT to provide the fuse data DTA with the error corrected as the internal OTP data DO. According to example embodiments, the OTP memory device 400 may not perform ECC encoding and ECC decoding, and the ECC engine may be omitted. In this case, the parity data FPRT is excluded from the OTP fuse set OFSij of FIG. 9.

FIG. 11 is a block diagram illustrating an example embodiment of an update selection circuit included in an OTP memory device according to example embodiments.

Referring to FIG. 11, an update selection circuit 550 may include a decryption circuit DCR, a buffer BF, and a multiplexer MX.

In an example embodiment, the memory controller 100 of FIG. 3 may encrypt external OTP data DE and transmit the encrypted external OTP data DE′ to the semiconductor memory device 200. The decryption circuit DCR of the update selection circuit 550 may decrypt the encrypted external OTP data DE′ and restore the external OTP data DE. According to example embodiments, the decryption circuit DCR may be omitted, in which case the memory controller 100 may transmit the external OTP data DE to the semiconductor memory device 200. The buffer BF may buffer and store the received external OTP data DE. The multiplexer MX may selectively output the internal OTP data DO or the external OTP data DE based on the update selection signal USEL.

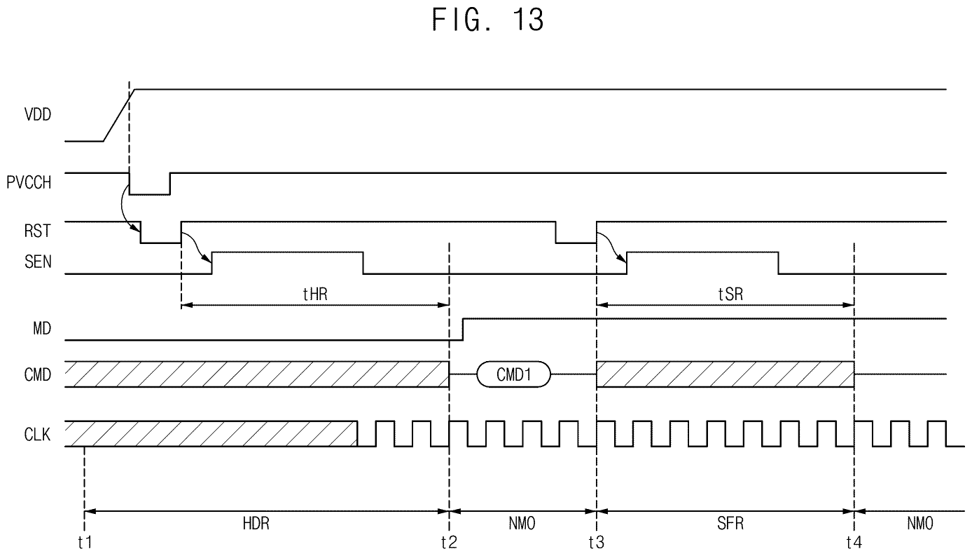

FIGS. 12 and 13 are timing diagrams illustrating example embodiments of operations in a preset mode and a vector mode of an OTP memory device according to example embodiments.

Referring to FIGS. 5, 7, 11, and 12, the OTP memory device 400 may selectively operate in a preset mode PRM or a vector mode VTM based on a mode signal MD. For example, as shown in FIG. 12, a logic low level of the mode signal MD may indicate the preset mode PRM, and a logic high level of the mode signal MD may indicate the vector mode VTM.

The control logic circuit 210 of FIG. 5 may generate the mode signal MD based on a mode control value stored in one of the mode registers 212. The mode control value may be set through a mode register write command MRW provided from the memory controller 100.

The control circuit 510 of the OTP memory device 400 activates the detection signal SEN in the preset mode PRM and the vector mode VTM, respectively, and a sensing operation for reading internal OTP data DO from the OTP cell array 510 may be performed while the detection signal SEN is activated as described above with reference to FIG. 10. The control circuit 510 may deactivate the update selection signal USEL to a logic low level in the preset mode PRM. Meanwhile, the control circuit 510 may control the timing at which the update selection signal USEL is activated to a logic high level based on the update address UADDR in the vector mode VTM. The update address UADDR indicates the range or location of information included in the external OTP data DE. The control circuit 510 may activate the update selection signal USEL in synchronization with the timing at which the internal OTP data DO corresponding to the external OTP data DE is output.

The multiplexer MX of the update selection circuit 550 may selectively output the internal OTP data DO or the external OTP data DE based on the update selection signal USEL.

The multiplexer MX may provide the internal OTP data DO as the updated OTP data DU in the preset mode PRM based on the deactivated update selection signal USEL.

In the vector mode VTM, the multiplexer MX may output the internal OTP data DO during the deactivation period of the update selection signal USEL and output the external OTP data DE during the activation period of the update selection signal USEL. The multiplexer MX may output the updated OTP data DU by selective output based on the update selection signal USEL. As a result, the update selection circuit 550 of FIG. 11 may provide the updated OTP data DU by replacing at least a portion of the internal OTP data DO with the external OTP data DE.

Referring to FIGS. 5, 7, and 13, at a first time point t1, an external power supply voltage VDD is applied, a power-on sequence is initiated, and a hard reset operation HDR may be performed. When the level of the external power supply voltage VDD reaches a predetermined reference power supply voltage level, the semiconductor memory device 200 may activate the power-up detection signal PVCCH to a logic low level for a predetermined period of time, and may activate a reset signal RST to a logic low level for a predetermined period of time in response to the activation of the power-up detection signal PVCCH.

The control circuit 510 of the OTP memory device 400 may perform a sensing operation by activating the detection signal SEN to a logic high level in response to the activation of the reset signal RST. While performing the hard reset operation HDR, the control logic circuit 210 of the semiconductor memory device 200 may maintain the mode signal MD in a deactivated state. As a result, the OTP memory device 400 may operate in the preset mode PRM while performing the hard reset operation HDR by activating the reset signal RST in the power-on sequence of the semiconductor memory device 200.

When the power-on sequence ends at a second time point t2, the semiconductor memory device 200 may receive a command, an address, and data from the memory controller 100 and perform a normal operation NMO. After the power-on sequence ends, the control logic circuit 210 may transition the mode signal MD to an activated state according to the mode control value of the mode register as described above.

The update address UADDR and the external OTP data DE may be transmitted from the memory controller 100 to the semiconductor memory device 200 together with the command CMD1. The command CMD1 of FIG. 13 may correspond to the update command UCMD as described above.

Thereafter, the control logic circuit 210 may activate the reset signal RST to a logic low level for a predetermined period of time while the external power supply voltage maintains a normal level, and a soft reset operation SFR may be performed at a third time point t3. The mode signal MD may be kept activated while performing the soft reset operation SFR. As a result, the OTP memory device 400 may operate in the vector mode VTM while receiving the external OTP data DE from the memory controller 100 during the normal operation NMO after the power-on sequence of the semiconductor memory device 200 is completed and reactivating the reset signal RST to perform the soft reset operation SFR.

At a fourth time point t4 when the soft reset operation SFR is terminated, the semiconductor memory device 200 may perform the normal operation NMO again.

As such, since the semiconductor memory device 200 cannot receive the external OTP data DE from the memory controller 100 while the hard reset operation HDR is performed, the OTP memory device 400 may operate in the preset mode PRM. Thereafter, after receiving external OTP data DE from the memory controller 100, the OTP memory device 400 may operate in the vector mode VTM based on the received external OTP data DE while performing the soft reset operation SFR.

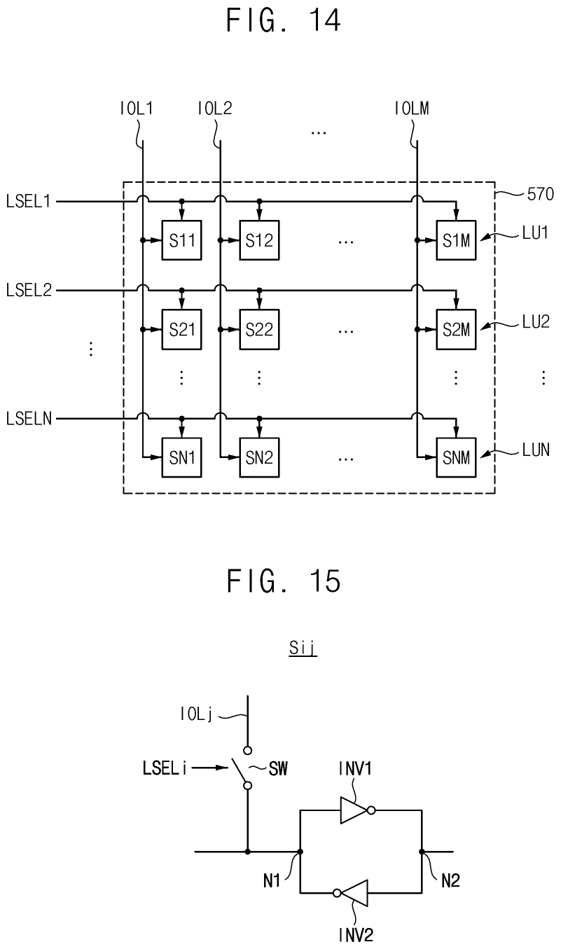

FIG. 14 is a diagram illustrating an example embodiment of a latch circuit included in an OTP memory device according to example embodiments.

Referring to FIG. 14, a latch circuit 570 may include N*M 1-bit latches S11 to SNM that store N*M fuse bits provided through input/output lines IOL1 to IOLM (M is a natural number equal to or greater than 2) during N unit cycles (N is a natural number equal to or greater than 2). The 1-bit latches S11 to SNM may be grouped into N latch units LU1 to LUN. The first latch unit LU1 includes M 1-bit latches S11 to S1M forming a first row, the second latch unit LU2 includes M 1-bit latches S21 to S2M forming a second row, and in the same way, the Nth latch unit LUN may include M 1-bit latches SN1 to SNM forming an Nth row.

The input/output lines IOL1 to IOLM are commonly connected to the latch units LU1 to LUN. The latch units LU1 to LUN may receive latch selection signals LSEL1 to LSENL that are sequentially activated, respectively, and may be sequentially enabled in response to the latch selection signals LSEL1 to LSENL. The 1-bit latches S11 to S1M included in the first latch unit LU1 are enabled when the first latch selection signal LSEL1 is activated and store the fuse bits of the first unit period, which are read out through the first bitline group, the 1-bit latches S21 to S2M included in the second latch unit LU2 are enabled when the second latch selection signal LSEL2 is activated and store the data bits of the second unit period which are read out through the second bitline group, and in this manner, the 1-bit storage elements SN1 to SNM included in the Nth latch unit LUN are enabled when the Nth loading selection signal LSELN is activated and store the data bits of the Nth unit period, which are read out through the Nth bitline group. As a result, N*M data bits may be sequentially stored in the latch circuit 570 in response to N latch selection signals (LSEL1 to LSENL) that are sequentially activated.

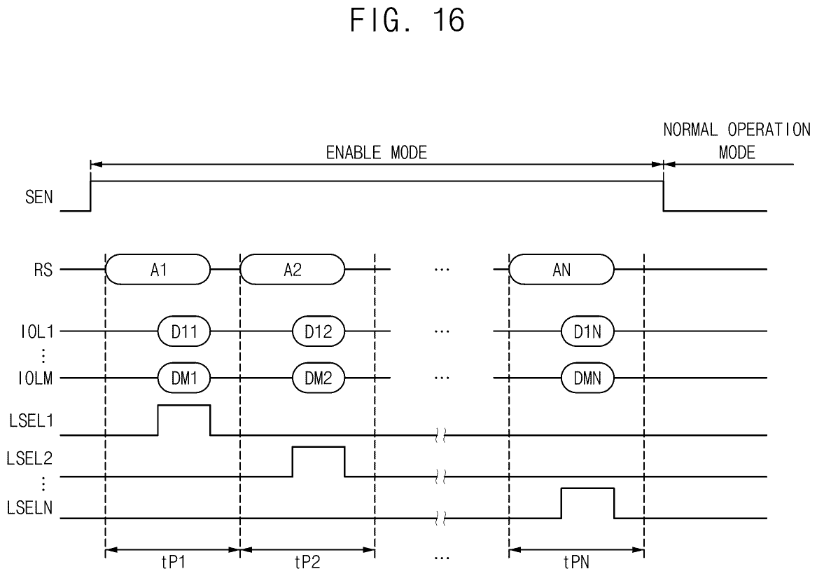

FIG. 15 is a circuit diagram illustrating an example embodiment of a 1-bit latch included in the latch circuit of FIG. 14.

Referring to FIG. 15, a 1-bit latch Sij included in a latch circuit 570 may include two inverters INV1 and INV2 and a switch SW where inputs and outputs of the two inverters INV1 and INV2 are connected in a cross manner between two nodes N1 and N2. The 1-bit latch Sij may latch a fuse bit provided through a corresponding input/output line IOLj through the switch SW that is turned on when a corresponding latch selection signal LSELi is activated.

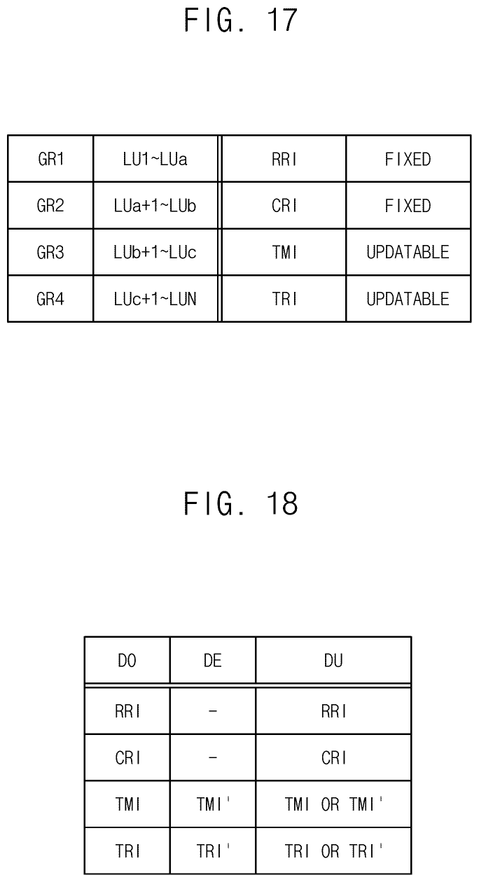

FIG. 16 is a timing diagram illustrating an example embodiment of an operation of an OTP memory device according to example embodiments.

Referring to FIGS. 7, 14, 15, and 16, when the detection signal SEN is activated, the internal OTP data DO may be read from the OTP cell array 410 of the OTP memory device as described above, and the updated OTP data DU may be output from the update selection circuit 550. Although FIG. 16 illustrates a case where the detection signal SEN is activated to a logic high level, the detection signal SEN may also be activated to a logic low level. The control circuit 510 may generate a plurality of latch selection signals LSEL, i.e., first to Nth latch selection signals LSEL1 to LSENL, which are sequentially activated based on a row selection signal RS that changes sequentially in each of the unit periods tP1 to tPN. During the first unit period tP1, the first latch selection signal LSEL1 may be activated, during the second unit period tP2, the second latch selection signal LSEL2 may be activated, and in the same manner, during the Nth unit period tPN, the Nth latch selection signal LSELN may be activated.

The row selection signal RS may indicate the first address A1 in the first unit period tP1, the second address A2 in the second unit period tP2, and in the same manner, the Nth address AN in the Nth unit period tPN. In an example embodiment, the addresses A1 to AN may sequentially increase or sequentially decrease. As illustrated in FIG. 16, the unit periods tP1 to tPN may correspond to the activation periods of one row of the OTP cell array.

In response to sequentially activated latch selection signals LSEL1 to LSENL, N*M fuse bits provided through bitlines may be sequentially stored in the latch circuit 570 through the input/output lines IOL1 to IOLM. During the first unit period tP1, the first fuse bits D11 to DM1 transmitted through the input/output lines IOL1 to IOLM in response to the activated first latch selection signal LSEL1 are stored in the first latch unit LU1 of the latch circuit 570. During the second unit period tP2, the second fuse bits D12 to DM2 transmitted through the input/output lines IOL1 to IOLM in response to the activated second latch selection signal LSEL2 are stored in the second latch unit LU2 of the latch circuit 570. In the same manner, during the Nth unit period tPN, the Nth fuse bits D1N to DMN transmitted through the input/output lines IOL1 to IOLM in response to the activated Nth latch selection signal LSELN may be stored in the Nth latch unit LUN of the latch circuit 570.

FIG. 17 is a diagram illustrating example embodiments of information stored in an OTP memory device according to example embodiments, and FIG. 18 is a diagram illustrating an example embodiment of an operation of an update selection circuit included in an OTP memory device according to example embodiments.

Referring to FIGS. 17 and 18, information stored in an OTP cell array may be grouped into a first group GR1 of row repair information RRI, a second group GR2 of column repair information CRI, a third group GR3 of test mode register set (TMRS) information TMI, and a fourth group GR4 of trimming information TRI.

The row repair information RRI is information for repairing defective wordlines of the memory cell array 310 of FIG. 5, the column repair information CRI is information for repairing defective bitlines of the memory cell array 310, the TMRS information TMI is information for setting test conditions of the semiconductor memory device 200, and the trimming information TRI is information for setting voltage levels and signal timing of the semiconductor memory device 200.

As illustrated in FIG. 17, the latch units LU1 to LUN of FIG. 14 described above may also be grouped according to the type of information. A plurality of latch units LU1 to LUa may be allocated to the first group GR1, a plurality of latch units LUa+1 to LUb may be allocated to the second group GR2, a plurality of latch units LUb+1 to LUc may be allocated to the third group GR3, and a plurality of latch units LUc+1 to LUN may be allocated to the fourth group GR4. The OTP memory device 400 may store the row repair information RRI, the column repair information CRI, the TMRS information TMI, and the trimming information TRI, information by information, that is, by group of latch units.

For example, about 500 to 600K OTP cells may be allocated for the row repair information RRI and the column repair information CRI, and about 10 to 20K OTP cells may be allocated for the TMRS information TMI and the trimming information TRI. The size of the row repair information RRI and the column repair information CRI is relatively very large, so it may not be suitable for updating using the external OTP data DE. In order to sense and transmit such large-sized information, the aforementioned soft reset operation SFR takes a long time and may cause a performance degradation of the semiconductor memory device. In addition, the row repair information RRI and the column repair information CRI may be updated by introducing a technology such as post package repair (PPR).

According to example embodiments, the aforementioned external OTP data DE may be data that replaces at least a portion of the TMRS information TMI and the trimming information TRI excluding the row repair information RRI and the column repair information CRI. In other words, the row repair information RRI and the column repair information CRI may be fixed, and the TMRS information TMI and the trimming information TRI may be updatable.

As illustrated in FIG. 18, the external OTP data DE may include at least a portion of the TMRS information TMI and the trimming information TRI excluding the row repair information RRI and the column repair information CRI.

The update selection circuit 550 of the OTP memory device 400 may output the internal OTP data DO corresponding to the row repair information RRI and the column repair information CRI as the updated OTP data DU, regardless of the preset mode PRM or the vector mode VTM. On the other hand, the TMRS information TMI and/or the trimming information TRI of the internal OTP data DO may be replaced with the TMRS information TMI′ and/or the trimming information TRI′ of the external OTP data DE.

FIG. 19 is a block diagram illustrating a semiconductor memory device including an OTP memory according to example embodiments.

Referring to FIG. 19, a memory device 200 may be configured to include a control logic circuit 210, an address register 220, an address decoder 260, a memory cell array 310, an input/output circuit 290, and an OTP memory device 400. The description overlapping with FIGS. 5 and 7 is omitted below.

The control logic circuit 210 receives a plurality of control signals (/CS, /WE, /CAS, and /AS) 70 through command pins 75, receives an address signal (ADDR1 to ADDRn) 80 through address pins 85, and controls the address decoder 260 that accesses the memory cell array 310 based on the command and address signals 80 indicated by the received control signals 70. In addition, the control logic circuit 210 may receive a clock enable signal /CKE, a clock signal CK, and an inverted clock signal /CK.

The address register 220 receives the address signal 80 through the address pins 85 and provides the received address signal 80 to the control logic circuit 210 and the address decoder 260 in synchronization with the clock signal CK or the inverted clock signal /CK.

The input/output circuit 560 provides data DQ1 to DQk (90) to the memory cell array 540 or receives data 90 from the memory cell array 540 and provides the received data 90 to the outside through the data pins 95. Through the data pins 95, the read data from the memory cell array 310 may be transmitted to the memory controller and the write data to be stored in the memory cell array 310 may be received from the memory controller.

The control logic circuit 210 includes a command decoder 210 and mode registers 211. The command decoder 211 decodes the command indicated by the plurality of control signals 70 and provides a mode register set (MRS) command MRS_CMD to the mode registers 212. The mode registers 212 may set the operation mode of the memory device 200 in response to the MRS command MRS_CMD provided from the command decoder 211. The operation mode may include an MRS mode, a test mode, a normal operation mode, and the like. According to example embodiments, the mode control value may be set through the MRS command MRS_CMD, i.e., the mode register write command MRW, provided from the memory controller 100. The above-described mode signal MD may be generated based on the mode control value stored in one of the mode registers 212.

In an example embodiment, the external OTP data DE may be received from the memory controller via data pins 95. In addition, the update address UADDR indicating a range of information included in external OTP data DE may be received from the memory controller through the address pins 85. For example, the update address UADDR may indicate an address of an OTP cell array corresponding to all or a portion of the TMRS information TMI included in the external OTP data DE.

FIG. 20 is a circuit diagram illustrating an example embodiment of an OTP cell included in an OTP memory device according to example embodiments.

Referring to FIG. 20, an OTP cell UCa may include an anti-fuse AF and a readout transistor TR.

The anti-fuse AF is connected between a voltage wordline WLP and an intermediate node NI. The readout transistor TR is connected between the intermediate node NI and a bitline BL, and a gate electrode is connected to the readout wordline WLP.

The anti-fuse AF may be implemented as a MOS (metal oxide semiconductor) transistor. In an example embodiment, as shown in FIG. 20, the MOS transistor may have a drain electrode that is floated, a source electrode that is connected to the intermediate node NI, and a gate electrode that is connected to a corresponding voltage wordline WLP.

An anti-fuse, which is an example of a component included in a cell of an OTP memory, is a resistive fuse element that has electrical characteristics opposite to those of a fuse element, and has a high resistance value in an unprogrammed state and a low resistance value in a programmed state.

An anti-fuse is generally configured in a form in which a dielectric is inserted between conductors, and the anti-fuse is programmed by applying a high voltage through the conductors at both ends of the anti-fuse for a sufficient period of time to destroy the dielectric between the two conductors. As a result of the program, the conductors at both ends of the anti-fuse are short-circuited, such that a low resistance value may be obtained. An OTP memory of the anti-fuse type is a memory that is programmed by electrically short-circuiting a fuse by applying a high voltage to both ends of a MOS capacitor of a thin gate oxide film, and has a small cell area and a low-power function. The anti-fuse has the advantage of being able to implement a device and being able to program in byte units with low current consumption during programming.

In the program mode, a relatively high voltage level program voltage is applied to the voltage wordline WLP, and in the read mode, a read voltage (lower than the program voltage) is applied to the voltage wordline WLP. In the program mode and the read mode, a selection voltage having a voltage level that may turn on the read transistor TR according to the row address RADDR is applied to the read wordline WLR.

In the program mode, a program allowance voltage is applied to a bitline to which an OTP cell to be programmed is connected, and a program inhibit voltage higher than the program allowance voltage is applied to a bitline to which a non-programmed OTP cell is connected. In an example embodiment, the program allowance voltage may be set to a ground voltage. Meanwhile, the program inhibit voltage may be set to a power supply voltage together with the read voltage. The voltage levels of the operating voltages, such as the program voltage, the read voltage, the program allow voltage, and the program inhibit voltage, may be set in various ways depending on the characteristics of the OTP cell and the configuration of the OTP memory device.

In the program mode, the program voltage is applied to the voltage wordline WLP and the read transistor TR is turned on, such that the program voltage and the program allow voltage are applied to both ends of the anti-fuse AF, thereby performing the program of the anti-fuse AF.

FIG. 21 is a cross-sectional diagram illustrating an example embodiment of a structure of the OTP cell of FIG. 20.

Referring to FIG. 21, the anti-fuse AF and the read transistor TR included in the OTP cell UCa are formed on the same substrate P_SUB. The readout transistor TR includes a first gate 411 connected to a readout wordline WLR, a first gate insulating layer (GOX) 412 that insulates the first gate 411 from the substrate P_SUB, a first source region 413 and a first drain region 414 that are formed in an asymmetrical structure facing each other with respect to the first gate 411. The first source region 413 of the readout transistor TR is connected to a bitline BL. The anti-fuse AF includes a second gate 421 connected to a voltage wordline WLP, a second gate insulating layer (GOX) 422 that insulates the second gate 421 from the substrate P_SUB, a second source region 423 connected to the first drain region 414 of the readout transistor TR, and a floating second drain region 424. The second source region 423 of the anti-fuse AF may be connected to the first drain region 414 of the readout transistor TR through a wiring 427. The wiring 427 may include an interlayer connection structure such as a metal line on the upper side and a via for connecting it to the substrate surface. In another example embodiment, the second source region 423 of the anti-fuse AF and the first drain region 414 of the readout transistor TR may be integrated into one active region, in which case the wiring 427 may be omitted. For example, the substrate P_SUB may be doped with a P-type impurity, and the first source region 413, the first drain region 414, the second source region 423, and the second drain region 424 may be doped with an N-type impurity. The readout transistor TR may further include a first spacer 415 formed on both sidewalls of the first gate 411 and the first gate insulating layer 412, and the anti-fuse AF may further include a second spacer 425 formed on both sidewalls of the second gate 421 and the second gate insulating layer 422.

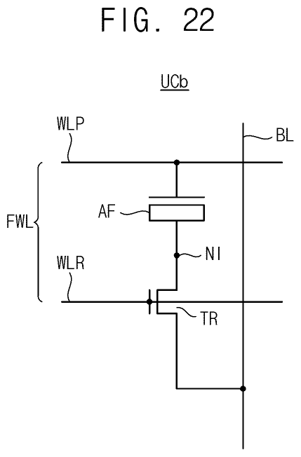

FIG. 22 is a circuit diagram illustrating an example embodiment of an OTP cell included in an OTP memory device according to example embodiments.

Referring to FIG. 22, an OTP cell UCb includes an anti-fuse AF and a readout transistor TR.

The anti-fuse AF is connected between a voltage wordline WLP and an intermediate node NI. The readout transistor TR is connected between the intermediate node NI and a bitline BL, and a gate electrode is connected to the readout wordline WLP.

The anti-fuse AF may be implemented as a MOS transistor. In an example embodiment, as illustrated in FIG. 21, the MOS transistor may be implemented as a MOS transistor in which a drain electrode and a source electrode are connected to the intermediate node NI, and a gate electrode is connected to a corresponding voltage wordline WLP.

The structure of the OTP cell UCb of FIG. 22 is similar to that described with reference to FIG. 21. However, in order to implement a MOS capacitor, wiring may be added to electrically connect the second source region 423 and the second drain region 424 illustrated in FIG. 22.

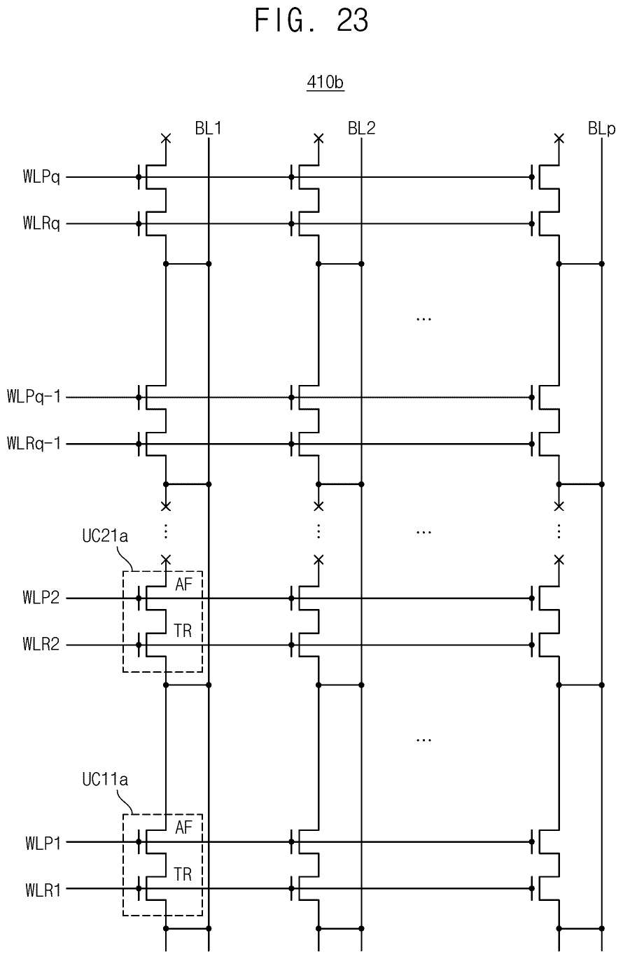

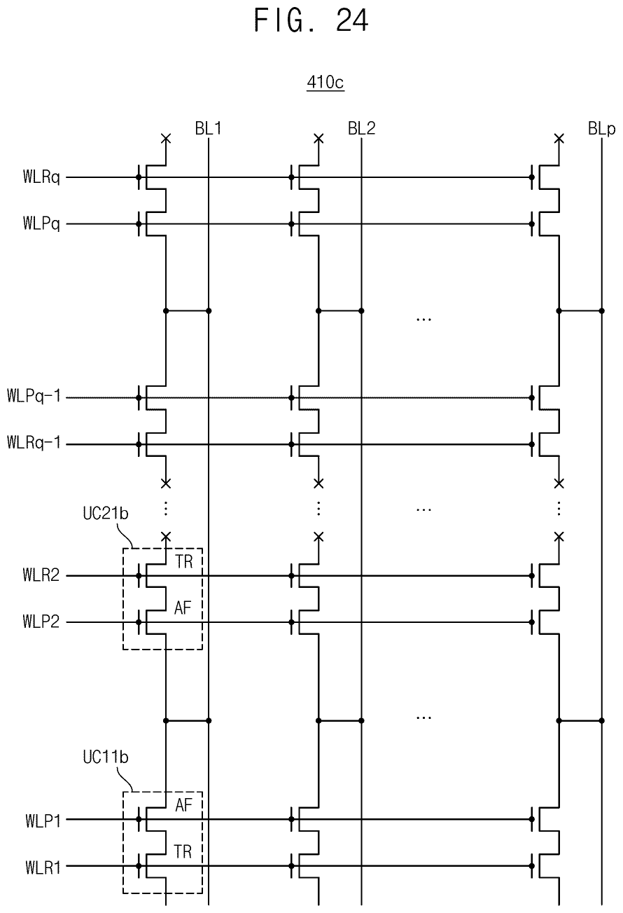

FIGS. 23 and 24 are circuit diagrams illustrating example embodiments of an OTP cell array included in an OTP memory device according to example embodiments.

Referring to FIG. 23, an OTP cell array 410b includes a plurality of OTP cells UC11a and UC21a connected to a plurality of read wordlines WLR1, . . . , WLRn, a plurality of voltage wordlines WLP1, . . . , WLPn, and a plurality of bitlines BL1, . . . , BLm, and arranged in a q*p (q, p are positive integers) matrix form. The gate of the readout transistor TR is connected to the corresponding readout wordline WLRx (x is an integer greater than or equal to 1 and less than or equal to q), and the source region of the readout transistor TR is connected to the corresponding bitline BLy (y is an integer greater than or equal to 1 and less than or equal to p).

The first terminal of the anti-fuse AF is connected to the corresponding voltage wordline WLPx, and the second terminal of the anti-fuse AF is connected to the drain region of the readout transistor TR.

As described above, the anti-fuse AF may be a MOSFET (Metal Oxide Semiconductor Field Effect Transistor). In this case, the gate of the anti-fuse AF may be the first terminal and be connected to the corresponding voltage wordline WLPx, the source region of the anti-fuse AF may be the second terminal and be connected to the drain region of the readout transistor TR, and the drain region of the anti-fuse AF may be floating. Each of the OTP cells UC11a and UC21a includes the anti-fuse AF and the readout transistor TR.

Referring to FIG. 24, an OTP cell array 410c includes a plurality of OTP cells UC11b and UC21b connected to a plurality of readout wordlines WLR1, . . . , WLRq, a plurality of voltage wordlines WLP1, . . . , WLPq and a plurality of bitlines BL1, . . . , BLp, and arranged in a q*p (q, p are positive integers) matrix form.

The OTP cell array 410c of FIG. 24 differs from the OTP cell array 410b of FIG. 23 in that every two OTP cells UC11b and UC21b form a pair.

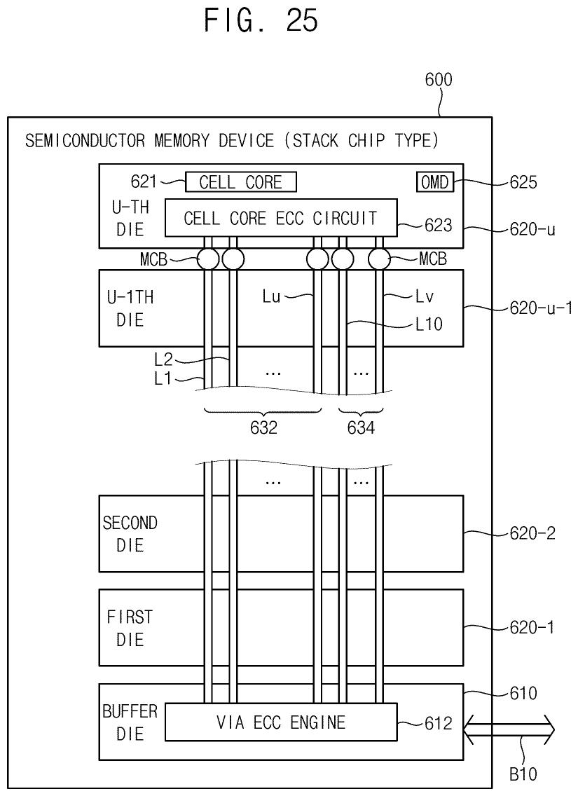

FIG. 25 is a block diagram illustrating a semiconductor memory device according to example embodiments.

Referring to FIG. 25, a semiconductor memory device 600 may include at least one buffer die 610 and a plurality of memory dies 620-1, 620-2, . . . , and 620-u (u is a natural number greater than or equal to 4) to provide analysis and repair functions of soft data fail in a stacked chip structure.

The plurality of memory dies 620-1, 620-2, . . . , 620-u may be stacked on top of the buffer die 610 and may communicate data through a plurality of through silicon via (hereinafter referred to as TSV) lines.

Each of the plurality of memory dies 620-1, 620-2, . . . , 620-u may include a cell core 621 having memory cells, a cell core ECC engine 622 that generates transmission parity bits using transmission data transmitted to the buffer die 610, and an OTP memory device (OMD) 625. The OTP memory device 625 may have a configuration that provides updated OTP data DU by replacing at least a portion of the internal OTP data DO with external OTP data DE as described above.

The buffer die 610 may include a via ECC engine 612 that generates error-corrected data by correcting a transmission error using transmission parity bits when a transmission error occurs in transmission data received through the plurality of TSV lines.

The semiconductor memory device 600 may be a stack chip type memory device or a stacked memory device that communicates the data and control signals through the TSV lines. The TSV lines may also be referred to as silicon through electrodes. A data TSV line group 632 formed on one memory die 620-u may be composed of TSV lines L1 to Lu, and a parity TSV line group 634 may be composed of TSV lines L10 to Lv. The TSV lines L1 to Lu of the data TSV line group 632 and the TSV lines L10 to Lv of the parity TSV line group 634 may be connected to micro bumps MCB correspondingly formed between a plurality of memory dies 620-1 to 620-u. Each of the plurality of memory dies 620-1 to 620-u may have DRAM cells composed of one access transistor and one storage capacitor. The semiconductor memory device 600 may have a 3D (three-dimensional) chip structure or a 2.5D chip structure to communicate with an external memory controller through a data bus B10. The buffer die 610 may be connected to an external memory controller through the data bus B10. The via ECC engine 612 checks whether a transmission error has occurred in transmission data received through a data TSV line group 632 using transmission parity bits received through a parity TSV line group 634. If a transmission error has occurred, the via ECC engine 612 corrects the transmission error for the transmission data using the transmission parity bits. If the number of bits of the transmission error cannot be corrected, the via ECC engine 612 may output information notifying the occurrence of a data error.

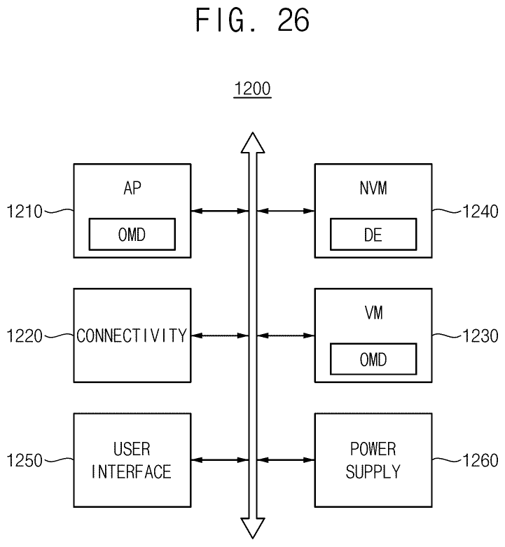

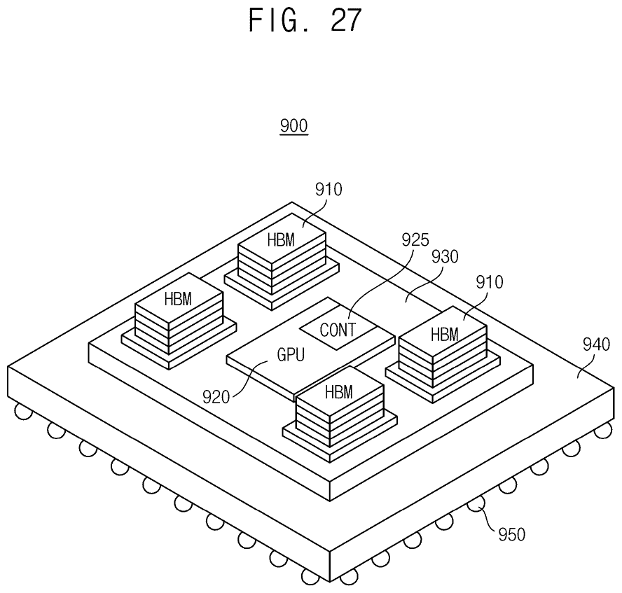

FIG. 26 is a block diagram illustrating a mobile system including an OTP memory device according to example embodiments.

Referring to FIG. 26, a mobile system 1200 includes an application processor 1210, a connectivity unit 1220, a semiconductor memory device 1230, a nonvolatile memory device 1240, a user interface 1250, and a power supply 1260. According to example embodiments, the mobile system 1200 may be any mobile system, such as a mobile phone, a smart phone, a personal digital assistant (PDA), a portable multimedia player (PMP), a digital camera, a music player, a portable game console, a navigation system, etc.

The application processor 1210 may execute applications that provide an Internet browser, a game, a video, etc. According to example embodiments, the application processor 1210 may include a single processor core or multiple processor cores. For example, the application processor 1210 may include a multi-core such as a dual core, a quad core, or a hexa-core. In addition, according to example embodiments, the application processor 1210 may further include a cache memory located internally or externally.

The communication unit 1220 may perform wireless or wired communication with an external device. For example, the communication unit 1220 may perform Ethernet communication, Near Field Communication (NFC), Radio Frequency Identification (RFID) communication, Mobile Telecommunication, memory card communication, Universal Serial Bus (USB) communication, etc. For example, the communication unit 1220 may include a baseband chipset and support communications such as GSM, GPRS, WCDMA, and HSxPA.

The semiconductor memory device 1230 may store data processed by the application processor 1210 or may operate as a working memory. For example, the semiconductor memory device 1230 may be a dynamic random access memory such as DDR SDRAM, LPDDR SDRAM, GDDR SDRAM, RDRAM, and the like.

The application processor 1210 and/or the semiconductor memory device 1230 include an OTP memory device OMD. As described above, the OTP memory device OMD may have a configuration that provides updated OTP data DU by replacing at least a portion of the internal OTP data DO with external OTP data DE.

The nonvolatile memory device 1240 may store a boot image for booting the mobile system 1200. For example, the nonvolatile memory device 1240 may be implemented as an Electrically Erasable Programmable Read-Only Memory (EEPROM), a Flash Memory, a Phase Change Random Access Memory (PRAM), a Resistance Random Access Memory (RRAM), a Nano Floating Gate Memory (NFGM), a Polymer Random Access Memory (PoRAM), a Magnetic Random Access Memory (MRAM), a Ferroelectric Random Access Memory (FRAM), or a similar memory.

For example, the application processor 1210 may perform the function of the aforementioned memory controller 100. The nonvolatile memory device 1240 may store the aforementioned external OTP data DE. The application processor 1210 may receive the external OTP data DE stored in the nonvolatile memory device 1240 and transmit the external OTP data DE to the semiconductor memory device 1230, in the aforementioned vector mode VTM.

The user interface 1250 may include one or more input devices such as a keypad, a touch screen, and/or one or more output devices such as a speaker, a display device. The power supply 1260 may supply an operating voltage of the mobile system 1200. In addition, according to example embodiments, the mobile system 1200 may further include a camera image processor (CIS), and may further include a storage device such as a memory card, a solid state drive (SSD), a hard disk drive (HDD), a CD-ROM, etc.

The mobile system 1200 or components of the mobile system 1200 may be mounted using various types of packages, for example, packages such as PoP (Package on Package), BGAs (Ball grid arrays), CSPs (Chip scale packages), PLCC (Plastic Leaded Chip Carrier), PDIP (Plastic Dual In-Line Package), Die in Waffle Pack, Die in Wafer Form, COB (Chip On Board), CERDIP (Ceramic Dual In-Line Package), MQFP (Plastic Metric Quad Flat Pack), TQFP (Thin Quad Flat-Pack), SOIC (Small Outline Integrated Circuit), SSOP (Shrink Small Outline Package), TSOP (Thin Small Outline Package), TQFP (Thin Quad Flat-Pack), SIP (System In Package), MCP (Multi Chip Package), WFP (Wafer-level Fabricated Package), WSP (Wafer-Level Processed Stack Package), etc.

FIG. 27 is a structural diagram illustrating a semiconductor package including a stacked memory device according to example embodiments.

Referring to FIG. 27, a semiconductor package 900 may include one or more stacked memory devices 910 and a graphic processor (GPU) 920, and the graphic processor 920 may include a memory controller (CONT) 925.

The stacked memory devices 910 and the graphic processor 920 may be mounted on an interposer 930, and the interposer 930 on which the stacked memory devices 910 and the graphic processor (920) are mounted may be mounted on a package substrate 940. The memory controller 925 may perform substantially the same function as the memory controller 100 of FIG. 3.

The stacked memory device 910 may be implemented in various forms, and according to an example embodiment, the stacked memory device 910 may be a memory device in the form of an HBM (High Bandwidth Memory) in which multiple layers are stacked. Accordingly, the stacked memory device 910 includes a buffer die and a plurality of memory dies, and the plurality of memory dies may include a cell core, a cell core ECC engine, and an OTP memory device, respectively.

The plurality of stacked memory devices 910 may be mounted on the interposer 930, and the graphic processor 920 may communicate with the plurality of stacked memory devices 910. As an example, each of the stacked memory devices 910 and the graphic processor 920 may include a physical area, and communication may be performed between the stacked memory devices 910 and the graphic processor 920 through the physical area.

Each of the stacked memory devices 910 may include an OTP memory device OMD. The OTP memory device OMD may have a configuration that provides updated OTP data DU by replacing at least a portion of the internal OTP data DO with external OTP data DE, as described above.

As described above, the semiconductor memory device including the OTP memory device according to example embodiments may increase yield and lifespan of the semiconductor memory device by efficiently replacing the internal OTP data read from the OTP cell array with the external OTP data. In addition, the semiconductor memory device including the OTP memory device according to example embodiments may increase degree of test freedom and improve test efficiency by testing the semiconductor memory device by replacing the internal OTP data with the external OTP data corresponding to various test conditions.

The inventive concept may be applied to any electronic devices and systems. For example, the inventive concept may be applied to systems such as a memory card, a solid state drive (SSD), an embedded multimedia card (eMMC), a universal flash storage (UFS), a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, a server system, an automotive driving system, a data center, etc.

The foregoing is illustrative of example embodiments and is not to be construed as limiting thereof. Although a few example embodiments have been described, those skilled in the art will readily appreciate that many modifications are possible in the example embodiments without materially departing from the present inventive concept.

What is claimed is:

1. A semiconductor memory device comprising:
a memory cell array including a plurality of memory cells storing data;
a one-time programmable (OTP) memory device configured to provide updated OTP data; and
a peripheral circuit configured to be initialized and control the memory cell array based on the updated OTP data,
wherein the OTP memory device includes:
an OTP cell array including a plurality of OTP cells;
a driving circuit configured to output internal OTP data by reading out information stored in the OTP cell array; and
an update selection circuit configured to receive external OTP data from an external device and selectively output the internal OTP data or the external OTP data to provide the updated OTP data.

2. The semiconductor memory device of claim 1, wherein the OTP memory device is configured to selectively operate in a preset mode or a vector mode based on a mode signal provided from the peripheral circuit.

3. The semiconductor memory device of claim 2, wherein the update selection circuit is configured to provide the internal OTP data as the updated OTP data in the preset mode, and provide the updated OTP data by replacing at least a portion of the internal OTP data with the external OTP data in the vector mode.

4. The semiconductor memory device of claim 2, wherein the peripheral circuit includes mode registers configured to store control values to control operation of the semiconductor memory device, and the peripheral circuit is configured to generate the mode signal based on a mode control value stored in one of the mode registers.

5. The semiconductor memory device of claim 4, wherein the mode control value is set based on a mode register write command provided from the external device.

6. The semiconductor memory device of claim 2, wherein the information stored in the OTP cell array includes row repair information to repair defective wordlines of the memory cell array, column repair information to repair defective bitlines of the memory cell array, test mode register set (TMRS) information to set test conditions of the semiconductor memory device, and trimming information to set voltage levels and signal timings of the semiconductor memory device.

7. The semiconductor memory device of claim 6, wherein the external OTP data is configured to replace at least a portion of the TMRS information and the trimming information excluding the row repair information and the column repair information.

8. The semiconductor memory device of claim 6, wherein the update selection circuit is configured to, regardless of the preset mode or the vector mode, output the internal OTP data corresponding to the row repair information and the column repair information as the updated OTP data.

9. The semiconductor memory device of claim 6, wherein the OTP memory device further includes:
a latch circuit configured to store the row repair information, the column repair information, the TMSR information and the trimming information, respectively, information by information.

10. The semiconductor memory device of claim 2, wherein the OTP memory device is configured to operate in the vector mode while the semiconductor memory device performs a hard reset operation by activating a reset signal during a power-on sequence.

11. The semiconductor memory device of claim 2, wherein the OTP memory device is configured to receive the external OTP data and operate in the vector mode while the semiconductor memory device performs a soft reset operation by activating a reset signal during a normal operation after a power-on sequence is completed.

12. The semiconductor memory device of claim 2, wherein the external device is a memory controller configured to control operation of the semiconductor memory device.

13. The semiconductor memory device of claim 12, wherein the external OTP data is stored in a nonvolatile memory device, and
wherein the memory controller is configured to receive the external OTP data from the nonvolatile memory device and transfer the external OTP data to the semiconductor memory device.

14. The semiconductor memory device of claim 12, wherein the memory controller is configured to encrypt the external OTP data and transfer the encrypted external OTP data to the semiconductor memory device, and
wherein the update selection circuit includes:
a decryption circuit configured to decrypt the encrypted external OTP data to restore the external OTP data.

15. The semiconductor memory device of claim 1, further comprising:
data pins configured to transmit read data that is read from the memory cell array to a memory controller and receive write data to be stored in the memory cell array from the memory controller, and
wherein the semiconductor memory device is configured to receive the external OTP data through the data pins from the memory controller.

16. The semiconductor memory device of claim 1, wherein the OTP memory device is configured to receive an update address indicating a range of information included in the external OTP data from the external device, and generate an update selection signal based on the update address, and
wherein the update selection circuit is configured to selectively output the internal OTP data or the external OTP data based on the update selection signal.

17. The semiconductor memory device of claim 1, wherein the semiconductor memory device is a dynamic random access memory (DRAM) device including DRAM cells.

18. The semiconductor memory device of claim 1, wherein the external device is a test device configured to test the semiconductor memory device.

19. A semiconductor memory device comprising:
a memory cell array including a plurality of memory cells storing data;
a one-time programmable (OTP) cell array including a plurality of OTP cells;
a driving circuit configured to output internal OTP data by reading out information stored in the OTP cell array;
an update selection circuit configured to receive external OTP data from an external device and selectively output the internal OTP data or the external OTP data to provide updated OTP data; and
a peripheral circuit configured to be initialized and control the memory cell array based on the updated OTP data.

20. A method of controlling a semiconductor memory device including an one-time programmable (OTP) device, comprising:
outputting internal OTP data by reading out information stored in an OTP cell array;
receiving external OTP data from a memory controller;
providing updated OTP data by selectively outputting the internal OTP data or the external OTP data; and
initializing the semiconductor memory device based on the updated OTP data.
